(19) United States
(12) Patent Application Publication
(10) Pub. No.: US 2017/0278461 A1
(43) Pub. Date: Sep. 28, 2017

(54) DRIVE METHOD FOR DISPLAY DEVICE AND DISPLAY DEVICE

(71) Applicant: JOLED INC., Tokyo (JP)

(72) Inventors: Tomoyuki MAEDA, Tokyo (JP); Masafumi MATSUI, Tokyo (JP)

(73) Assignee: JOLED INC., Tokyo (JP)

(21) Appl. No.: 15/504,866

(22) PCT Filed: Aug. 10, 2015
(86) PCT No.: PCT/JP2015/004018

§ 371 Date: Feb. 17, 2017

(30) Foreign Application Priority Data
Aug. 22, 2014 (JP) 2014-169704

(51) Int. Cl. G09G 3/3291

(52) U.S. Cl. CPC G09G 3/3291; G09G 2300/0871; G09G 2320/043; G09G 2310/0289; G09G 2310/0294

(57) ABSTRACT

There is provided a drive method for a display device in which a plurality of pixel circuits are disposed in rows and columns, each of the plurality of pixel circuits including a light emitter that emits light in an amount according to a magnitude of a current supplied, and a drive transistor that supplies a current according to a magnitude of a video signal to the light emitter. The drive method includes applying an initialization voltage across a gate and a source of the drive transistor by an initialization voltage adjustment unit in an initialization period for initializing the drive transistor, the initialization voltage being higher than a threshold voltage of the drive transistor and according to a state of deterioration of the drive transistor.

### TECHNICAL FIELD

The present disclosure relates to a drive method for a display device and the display device that displays image data by flowing a current through a light emitter disposed in each of pixels.

### BACKGROUND ART

Patent Literature (PTL) 1 discloses a display device that corrects the mobility of a drive transistor adaptively with respect to the luminance level of a pixel. In the display device, a second timing at which a sampling transistor assumes an OFF state is automatically adjusted according to a signal potential with respect to a first timing at which a switching transistor assumes an ON state. Specifically, a signal applied to a transistor is controlled so that when a signal charge of a video signal supplied from a signal line is high, a period for correcting the mobility of the drive transistor is decreased, and when a signal charge of a video signal supplied to the signal line is low, a period for correcting the mobility of the drive transistor is increased. Thus, the uniformity of the pixels in the display device is improved.

### CITATION LIST

### Patent Literature

[PTL 1] Japanese Unexamined Patent Application Publication No. 2008-310352

### SUMMARY OF INVENTION

### Technical Problem

It is an object of the present disclosure to reduce stress applied to transistors included in pixels at the time of initialization of the pixels to reduce deterioration of the transistors.

### Solution to Problem

A drive method for an EL display device according to an aspect of the present disclosure provides a drive method for a display device in which a plurality of pixels are disposed in rows and columns, each of the plurality of pixels including a light emitter that emits light in an amount according to a magnitude of a current supplied, and a drive transistor that supplies a current according to a magnitude of a video signal to the light emitter, the drive method including applying an initialization voltage across a gate and a source of the drive transistor by an initialization voltage adjustment unit in an initialization period for initializing the drive transistor, the initialization voltage being higher than a threshold voltage of the drive transistor and according to a state of deterioration of the drive transistor.

### Advantageous Effects of Invention

According to the present disclosure, it is possible to reduce applied to transistors included in pixels at the time of initialization of the pixels to reduce deterioration of the transistors.

### BRIEF DESCRIPTION OF DRAWINGS

[FIG. 1]

FIG. 1 is a graph illustrating an amount of current of a drive TFT for explaining the underlying knowledge forming basis of the present disclosure.

[FIG. 2]

FIG. 2 is a schematic diagram illustrating the configuration of a pixel circuit according to the underlying knowledge forming basis of the present disclosure.

[FIG. 3]

FIG. 3 is a schematic diagram of a pixel circuit according to an embodiment of the present disclosure.

[FIG. 4]

FIG. 4 is a timing chart for explaining the operation of the pixel circuit illustrated in FIG. 3.

[FIG. 5]

FIG. 5 is a graph illustrating a temporal change of a necessary voltage across the gate and source to cause a constant current to flow through a drive transistor.

[FIG. 6]

FIG. 6 is a graph illustrating a temporal change of a necessary voltage across the gate and source to cause a constant current to flow through a drive transistor, and an initialization voltage.

[FIG. 7]

FIG. 7 is a graph illustrating a temporal change of a necessary voltage across the gate and source to cause a constant current to flow through a drive transistor, and an initialization voltage.

### DESCRIPTION OF EMBODIMENTS

Hereinafter, an embodiment will be described in detail with reference to the drawings as needed. However, a detailed description more than necessary may be omitted. For instance, a detailed description of a well-known matter and a redundant description of substantially the same configuration may be omitted. This is to avoid unnecessarily redundant description in the following and to facilitate understanding by those skilled in the art.

It is to be noted that the accompanying drawings and the following description are provided for those skilled in the art to sufficiently understand the present disclosure and are not intended to limit the subject matter recited in claims.

### (Underlying Knowledge Forming Basis of Present Disclosure)

Hereinafter, the underlying knowledge forming basis of the present disclosure will be described before the details of the present disclosure are described.

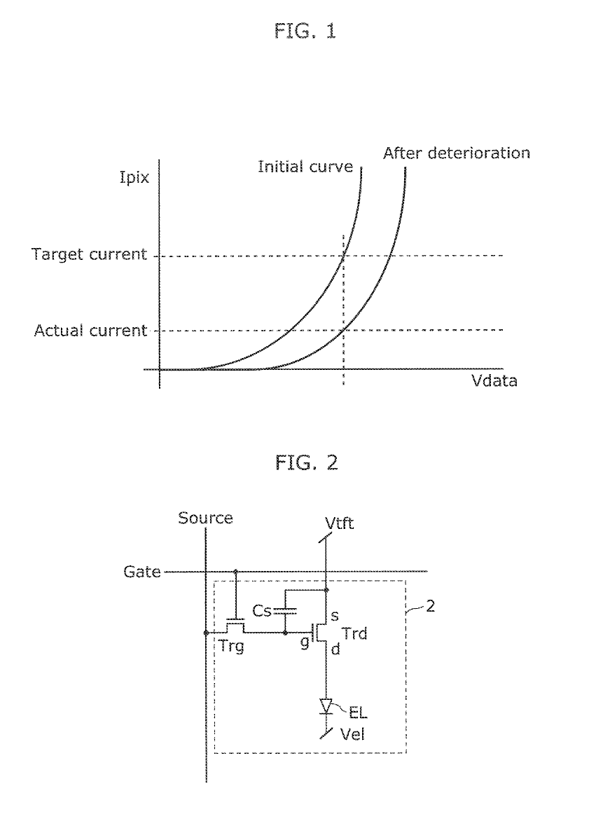

FIG. 1 is a graph illustrating an amount of current of a drive TFT for explaining the underlying knowledge forming basis of the present disclosure. FIG. 2 is a schematic diagram illustrating the configuration of a pixel circuit 2 according to the underlying knowledge forming basis of the present disclosure.

In a TFT (Thin Film Transistor) element, there is a problem in that when a voltage is applied thereto, a threshold voltage and the mobility change over time. In a pixel circuit of an OLEO (Organic Light Emitting Diode), there is a problem in that an initialization period is necessary for turning on a pixel and a voltage applied in the initialization period causes a drive transistor to deteriorate.

Specifically, a general pixel circuit 2 illustrated in FIG. 2 will be described. The pixel circuit 2 includes a drive transistor Trd, a switching transistor Trg, and an electrostatic capacitor Cs between the gate of the drive transistor Trd and the drain of the switching transistor Trg. In the pixel circuit 2, a video signal (voltage Vdata) is applied across the gate and source of the drive transistor Trd.

When the drive transistor Trd deteriorates, as illustrated in FIG. 1, even when the voltage Vdata is applied to the drive transistor Trd, the actual current flowing through the drive transistor Trd cannot reach a target current value in an initial curve before the drive transistor Trd deteriorates, and is lower than the target current value.

Here, since the initialization period is necessary only when image data is displayed, it is possible to reduce deterioration of the drive transistor Trd by shortening the initialization period or reducing an application voltage depending on a display state such as a non-light emission period.

Also, as an initialization voltage, it is necessary to apply a voltage on the assumption that the drive transistor Trd deteriorates and a threshold value of the drive transistor Trd is shifted. In an initial state where no deterioration occurs, it is necessary to apply a higher voltage, and thus pixels are stressed. This causes significant deterioration of transistors included in the pixels at the time of initialization. Thus, the magnitude of an initialization voltage is changed according to a state of deterioration of transistors, thereby reducing stress applied to the drive transistors Trd at the time of initialization and reducing deterioration.

Hereinafter, this embodiment will be described.

### Embodiment

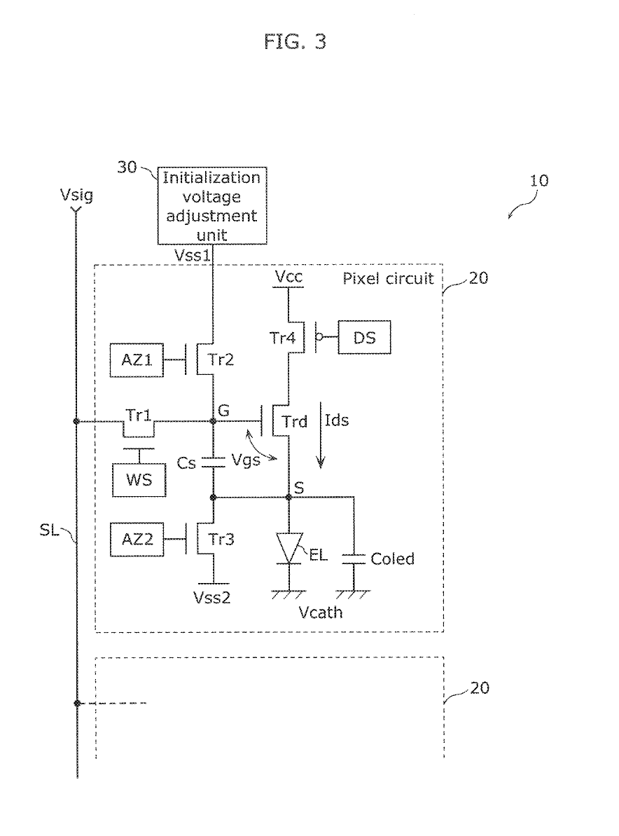

Hereinafter, a display device 10 according to the embodiment of the present disclosure will be described using FIG. 3 to FIG. 7.

### [1-1. Configuration of Display Device]

First, the configuration of the display device 10 will be described.

FIG. 3 is a schematic diagram illustrating the configuration of the display device 10 according to this embodiment.

As illustrated in FIG. 3, the display device 10 includes a pixel array in which a plurality of pixel circuits 20 are arranged in rows and columns, and an initialization voltage adjustment unit 30.

The pixel circuits 20 each includes a light emitter EL, a sampling transistor Tr1, a drive transistor Trd2, a first switching transistor Tr2, a second switching transistor Tr3, a third switching transistor Tr4, and a pixel capacitor Cs.

The light emitter EL is a diode-type organic electroluminescent (organic EL) device including an anode and a cathode, for instance. The light emitter EL emits light with a luminance according to a signal potential of a video signal by an output current Ids supplied from the drive transistor Trd during a predetermined light-emission period. It is to be noted that the light emitter EL is not limited to an organic EL device, and includes all devices that emit light by a current drive in general.

The sampling transistor Tr1 conducts according to a control signal supplied from a scanning line WS, and samples a signal potential of a video signal supplied from a signal line SL at the pixel capacitor Cs.

The pixel capacitor Cs applies an input voltage Vgs to the gate C of the drive transistor Trd according to the sampled signal potential of the video signal.

In an ON state, the drive transistor Trd supplies an output current Ids according to the input voltage Vgs to the light emitter EL.

The first switching transistor Tr2 is set to an ON state (electrically conductive) according to a control signal supplied from a scanning line AZ1, and sets the source S of the drive transistor Trd at a first potential Vss1.

The second switching transistor Tr3 is set to an ON state (electrically conductive) according to a control signal supplied from a scanning line AZ2, and sets the source S of the drive transistor Trd at a second potential Vss2.

The third switching transistor Tr4 is set to an ON state (electrically conductive) according to a control signal supplied from a scanning line DS, and connects the drive transistor Trd to a power supply Vcc. Thus, the third switching transistor Tr4 holds a voltage corresponding to a threshold voltage Vth of the drive transistor Trd at the pixel capacitor Cs, and compensates the effect of the threshold voltage Vth. In addition, the third switching transistor Tr4 is set to an ON state (electrically conductive) according to a control signal again supplied from the scanning line DS in a light emission period, and connects the drive transistor Trd to the power supply Vcc, then causes the output current Ids to flow through the light emitter EL.

Here, the sampling transistor Tr1, the first switching transistor Tr2, the second switching transistor Tr3, and the drive transistor Trd are N-channel type poly-Silicon TFT. Also, the third switching transistor Tr4 is P channel type poly-Silicon TFT. It is to be noted that the conduction type of each transistor is not limited to the aforementioned types, and N-channel type TFT and P-channel type TFT may be mixed as needed.

It is to be noted that in FIG. 3, signal potential Vgs of a video signal sampled by the sampling transistor Tr1, the input voltage Vgs and output current Ids of the drive transistor Trd, and capacitor component Coled included in the light emitter EL are also illustrated.

Furthermore, the display device 10 includes the initialization voltage adjustment unit 30. The initialization voltage adjustment unit 30 is connected to the other end opposite to one end of the first switching transistor Tr2, the one end connected to the gate G of the drive transistor Trd.

The initialization voltage adjustment unit 30 adjusts the voltage value and length of application time (initialization period) of the initialization voltage applied to the gate G of the drive transistor Trd, and outputs the initialization voltage to the gate G of the drive transistor Trd.

Hereinafter, the operation of the display device 10 including a pixel circuit 20 illustrated in FIG. 3 will be described.

### [1-2. Operation of Display Device]

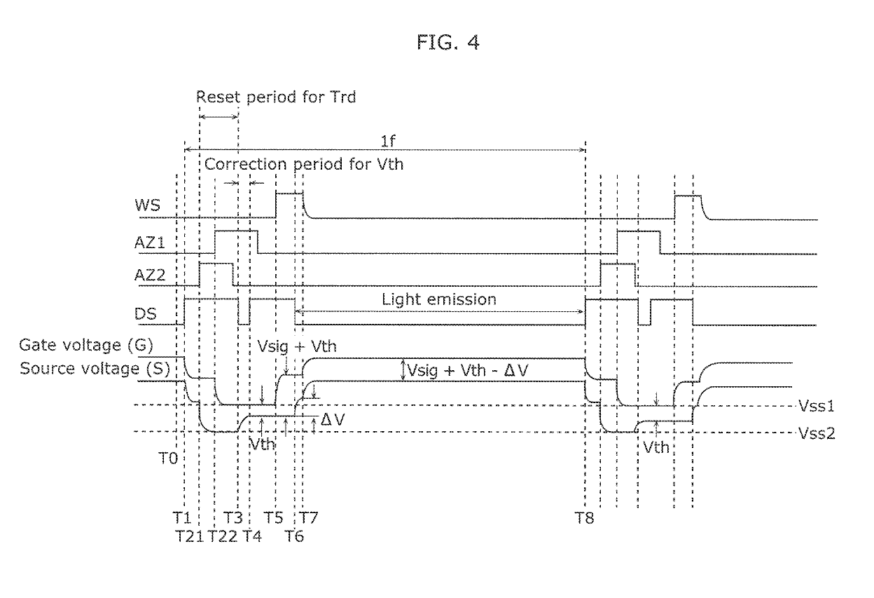

FIG. 4 is a timing chart for explaining the operation of the pixel circuit 20 illustrated in FIG. 3. It is to be noted that FIG. 4 illustrates the waveform of a control signal applied to each of the scanning lines WS, AZ1, AZ2 and DS along time axis T. In order to simplify the notation, each control signal is denoted by the same symbol as the symbol of a corresponding scanning line.

The sampling transistor Tr1, the first switching transistor Tr2, and the second switching transistor Tr3 are N-channel type, and thus are set to an ON state when the scanning lines WS, AZ1, AZ3 are at a high level, and are set to an OFF state when at a low level.

On the other hand, the third switching transistor Tr4 is P-channel type, and thus is set to an OFF state when the scanning line DS is at a high level, and is set to an ON state when at a low level.

It is to be noted that the timing chart illustrated in FIG. 4 shows the waveforms of the control signals WS, AZ1, AZ2, DS as well as change in the potential of the Gate G of the drive transistor Trd and change in the potential of the source S.

In the timing chart of FIG. 4, timing T1 to T8 is defined as 1 field (1f). During one field, each row of the pixel array in which a plurality of pixel circuits 20 are arranged in rows and columns is scanned sequentially. The timing chart also shows the waveforms of the control signals WS, AZ1, AZ2 to be applied to the pixels in one row.

Here, as illustrated in FIG. 4, at timing T0 before the field 1f starts, all the control signals WS, AZ1, AZ3, DS are at a low level. In this state, the sampling transistor Tr1, the first switching transistor Tr2, and the second switching transistor Tr3 which are N-channel type transistors are in an OFF state. On the other hand, the third switching transistor Tr4, which is a P-channel type transistor, is in an ON state.

Therefore, the drive transistor Trd is connected to the power supply Vcc via the third switching transistor Tr4 in an ON state. Thus, the drive transistor Trd supplies the output current Ids to the light emitter EL according to a predetermined input voltage Vgs.

Thus, at timing T0, the light emitter EL emits light. At this point, the input voltage Vgs applied to the drive transistor Trd is expressed by the difference between the potential of the gate G and the potential of the source S.

At timing T1 at which the field if starts, the control signal DS is switched from a low level to a high level. Thus, the third switching transistor Tr4 assumes an OFF state, and the drive transistor Trd is separated from the power supply Vcc. Therefore, the light emitter EL stops emitting light, and no-light emission period starts. Consequently, at timing T1, all of the sampling transistor Tr1, the first switching transistor Tr2, the second switching transistor Tr3, and the third switching transistor Tr4 assume an OFF state.

After timing T1, at timing T21, when the control signal AZ2 becomes a high level, the second switching transistor Tr3 assumes to an ON state. Thus, the source S of the drive transistor Trd is initialized to a predetermined potential Vss2. Subsequently, at timing T22, when the control signal AZ1 becomes a high level, the first switching transistor Tr2 assumes to an ON state. Thus, the gate G of the drive transistor Trd is initialized to a predetermined potential Vss1. Consequently, the Gate G of the drive transistor Trd is connected to the reference voltage Vss1, and the Source S is connected to the reference voltage Vss2.

Here, the relationship between the reference voltage Vss1, the reference voltage Vss2, and the threshold voltage Vth satisfies Vss1−Vss2>Vth, and setting of Vss1−Vss2=Vgs>Vth prepares for Vth correction to be performed at subsequent timing T3. It is to be noted that the period from timing T21 to timing T3 is the initialization period for the drive transistor Trd. Also, the initialization period is provided every one field without fail.

Let VthEL be a threshold voltage of the light emitter EL. The relationship between the threshold voltage VthEL of the light emitter EL and the reference voltage Vss2 is set to VthEL>Vss2. Thus, a negative bias is applied to the light emitter EL which assumes what is called a reverse bias state.

Furthermore, after the control signal AZ2 becomes a low level, at timing T3, the control signal DS becomes a low level. Thus, the transistor Tri assumes an OFF state, and the third switching transistor Tr4 assumes an ON state. Thus, the drain current Ids flows into the pixel capacitor Cs, and Vth correction operation is started.

At this point, the Gate G of the drive transistor Trd is maintained at Vss1, and the drain current Ids flows through the drive transistor Trd until the drive transistor Trd is cut off. When the drive transistor Trd is cut off, the potential of the source S of the drive transistor Trd becomes Vss1−Vth.

Subsequently, after the drive transistor Trd is cut off, when the control signal DS becomes a high level again at timing T4, the third switching transistor Tr4 assumes an OFF state. Furthermore, when the control signal AZ1 becomes a low level, the first switching transistor Tr2 assumes an OFF state. Thus, the threshold voltage Vth is held and fixed at the pixel capacitor Cs.

As described above, the period from timing T3 to timing T4 is the period in which the threshold voltage Vth of the drive transistor Trd is detected. It is to be noted that the period from timing T3 to timing T4 is referred to as Vth correction period.

Subsequently, at timing T4, the control signal DS becomes a high level again from a low level, and the control signal AZ1 becomes a low level from a high level. Subsequently, at timing T5, the control signal WS becomes a high level from a low level. Thus, signal potential Vsig of a video signal is written in the pixel capacitor Cs. Furthermore, at timing T6, the control signal DS becomes a low level from a high level. Consequently, the light emitter EL starts light emission.

Furthermore, by repeating the above-mentioned field if, light is emitted sequentially from the light emitters EL disposed in rows and columns according to the signal potential Vsig, and video data is obtained.

Here, the initialization voltage of the drive transistor Trd will be described.

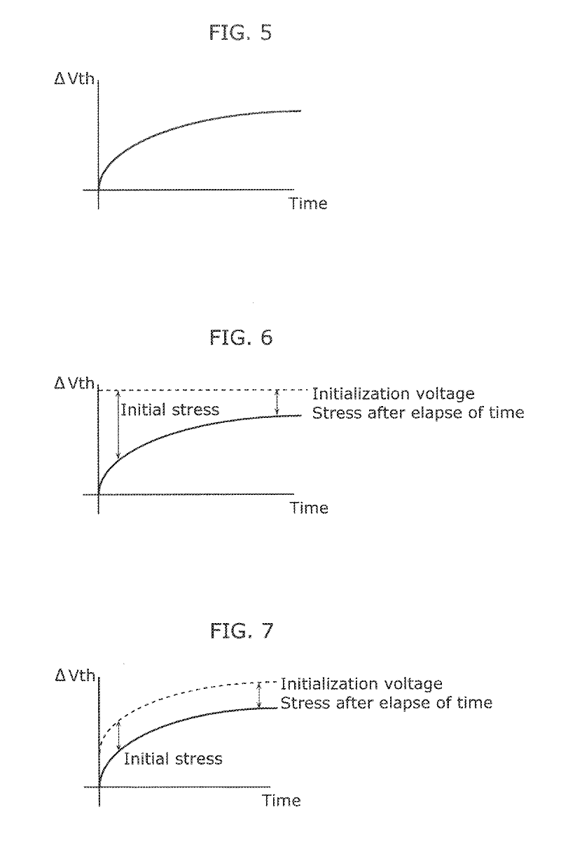

FIG. 5 to FIG. 7 are graphs illustrating a temporal change of a necessary voltage across the gate and source to cause a constant current to flow through the drive transistor Trd.

The drive transistor Trd deteriorates as time elapses. Specifically, when a constant voltage is applied to the gate of the drive transistor Trd, the current Ids flowing between the source and drain decreases as time elapses. Therefore, as illustrated in FIG. 5, a necessary voltage across the gate and source to cause a constant current to flow through the drive transistor Trd increases as time elapses.

Here, as illustrated in FIG. 6, when an initialization voltage is set to be constant regardless of elapsed time, the difference (initial stress) between the initialization voltage (the dashed line in FIG. 6) and a necessary voltage (the solid line in FIG. 6) across the gate and source to cause a constant current to flow through the drive transistor Trd in an initial stage of driving is greater than the difference (stress after elapse of time) between the initialization voltage and a necessary voltage across the gate and source to cause a constant current to flow through the drive transistor Trd after elapse of a predetermined time. Therefore, in an initial stage of driving, an excessive voltage is applied across the gate and source of the drive transistor, and thus a high stress (voltage) is applied to the drive transistor Trd, which causes further deterioration of the drive transistor Trd than in the elapse of time.

Thus, as illustrated in FIG. 7, an initialization voltage according to a state of deterioration of the drive transistor Trd due to elapse of lime is applied to the drive transistor Trd.

Specifically, the initialization voltage has a voltage value obtained by adding a predetermined voltage to the threshold value Vth of the drive transistor Trd, the predetermined voltage varying by an amount equal to an amount of variation ΔVth in the threshold voltage. Therefore, as illustrated in FIG. 7, the difference between the threshold voltage (solid line) of the drive transistor Trd and the initialization voltage (dashed line) is constant. Consequently, it is possible to avoid high stress application to the drive transistor Trd in an initial stage of driving.

Also, the initialization voltage is low in an initial stage of driving, and is increased sequentially as time elapses according to a state of deterioration of the drive transistor Trd. Therefore, it is possible to protect against high stress application to the drive transistor Trd in an initial stage of driving, and to reduce deterioration of the drive transistor Trd.

Here, as illustrated in FIG. 7, the initialization voltage adjustment unit 30 sets the initialization voltage so that the difference (initial stress) between the initialization voltage and a necessary voltage across the gate and source to cause a constant current to flow through the drive transistor Trd in an initial stage of driving is substantially the same as the difference (stress after elapse of time) between the initialization voltage and a necessary voltage across the gate and source to cause a constant current to flow through the drive transistor Trd after elapse of a predetermined time. Application of the set initialization voltage across the gate and source of the drive transistor Trd prevents an excessive voltage from being applied to the drive transistor Trd in an initial stage of driving. Therefore, deterioration of the drive transistor Trd can be reduced.

Here, the initialization voltage adjustment unit 30 changes at least one of the initialization voltage value and the initialization period according to a state of deterioration of the drive transistor Trd. It is to be noted that the initialization voltage adjustment unit 30 preferably chances the length of the initialization period.

The initialization voltage adjustment unit 30 pre-sets at least one of the initialization voltage value and the length of the initialization period according to a state of deterioration of the drive transistor Trd. The initialization voltage adjustment unit 30 then applies the set initialization voltage to the drive transistor Trd. For instance, as a cumulative usage time of the display device 10 changes like 0 hour, 100 hours, 1000 hours, the initialization voltage may be set to 2V, 2.1V, 2.5V.

Alternatively, the initialization voltage adjustment unit 30 may apply an initialization voltage across the gate and source of the drive transistor Trd in the set initialization period. For instance, as a cumulative usage time of the display device 10 changes like 0 hour, 100 hours, 1000 hours, the initialization voltage of 4V may be applied for 100 psec, 200 psec, 300 psec.

Consequently, the initialization voltage adjustment unit 30 can apply a stable initialization voltage to the drive transistor.

Here, a state of deterioration of the drive transistor Trd may be obtained from, for instance, measurement data of voltage or current obtained in the past or obtained by calculating a theoretical value each time.

When determining at least one of the initialization voltage value and the length of the initialization period, the initialization voltage adjustment unit 30, before applying an initialization voltage across the gate and source of the drive transistor Trd, estimates a state of deterioration of the drive transistor Trd from video data. The initialization voltage adjustment unit 30 then sets an initialization voltage according to the estimated state of deterioration of the drive transistor. Specifically, change in the luminance of the light emitter EL is observed visually or with a camera or the like in the video data, thereby making it possible to simply estimate a state of deterioration of the drive transistor Trd and to apply an optimal initialization voltage across the gate and source of the drive transistor Trd.

It is to be noted that when pre-setting the initialization voltage value, he initialization voltage adjustment unit 30 may estimate a state of deterioration of the drive transistor Trd not only from the video data but also the threshold voltage of the drive transistor Trd or measurement data obtained by measuring a current which flows through the drive transistor Trd, and may set an initialization voltage according to the estimated state of deterioration of the drive transistor. Thus, the initialization voltage adjustment unit 30 can estimate a state of deterioration of the drive transistor Trd with high accuracy, and can apply an optimal initialization voltage across the gate and source of the drive transistor Trd. As a means to measure a current, a path which allows measurement of current may be designed in a pixel in the panel, or a pixel for measuring a current may be provided outside a display area in the panel or outside the panel.

As described above, with the display device according to this embodiment, an initialization voltage is increased sequentially from the value in an initial stage of driving according to a state of deterioration of the drive transistor Trd, and thus it is possible to protect against high stress application to the drive transistor Trd in an initial stage of driving, arid to reduce deterioration of the drive transistor Trd.

### [1-3. Effects]

As described above, a drive method for a display device according to an aspect of the present disclosure provides a drive method for a display device in which a plurality of pixels are disposed in rows and columns, each of the plurality of pixels including a light emitter that emits light in an amount according to a magnitude of a current supplied, and a drive transistor that supplies a current according to a magnitude of a video signal to the light emitter the drive method including applying an initialization voltage across a gate and a source of the drive transistor by an initialization voltage adjustment unit in an initialization period for initializing the drive transistor, the initialization voltage being higher than a threshold voltage of the drive transistor and according to a state of deterioration of the drive transistor.

With this configuration, an excessive voltage is not applied to the drive transistor in an initial stage of driving. Therefore, deterioration of the drive transistor can be reduced.

Also, the initialization voltage may have a voltage value obtained by adding a predetermined voltage to the threshold value of the drive transistor, the predetermined voltage varying by an amount equal to an amount of variation in the threshold voltage.

With this configuration, the difference between the threshold voltage (solid line) of the drive transistor Trd and the initialization voltage (dashed line) is constant. Consequently, it is possible to avoid high stress application to the drive transistor Trd in an initial stage of driving.

Also, the initialization voltage may be increased as time elapses.

With this configuration, even in a drive transistor with deterioration of reduced current flow through the drive transistor with elapse of time, a constant current can be flown through the drive transistor.

Also, the initialization voltage adjustment unit may adjust the length of the initialization period according to a state of deterioration of the drive transistor.

With this configuration, a stable initialization voltage can be applied to the drive transistor. Thus, it is possible to further reduce deterioration of the drive transistor.

Also, before an initialization voltage is applied across the gate and source of the drive transistor, the initialization voltage adjustment unit may estimate a state of deterioration of the drive transistor from video data obtained by light-emission of the light emitter, and may set the initialization voltage.

With this configuration, it is possible to simply estimate a state of deterioration of the drive transistor and to apply an optimal initialization voltage to the drive transistor.

Also, before an initialization voltage is applied across the gate and source of the drive transistor, the initialization voltage adjustment unit may estimate a state of deterioration of the drive transistor from the threshold voltage of the drive transistor or measurement data of current which flows through the drive transistor, and may set the initialization voltage.

With this configuration, it is possible to estimate a state of deterioration of the drive transistor with high accuracy, and to apply an optimal initialization voltage across the gate and source of the drive transistor.

Also, a display device according to an aspect of the present disclosure includes; a plurality of pixels which are disposed in rows and columns, and each of which includes a light emitter that emits light in an amount according to a magnitude of a current supplied, and a drive transistor that supplies a current according to a magnitude of a video signal to the light emitter; and an initialization voltage adjustment unit configured to apply an initialization voltage for initializing the drive transistor to the drive transistor, wherein the initialization voltage adjustment unit is configured to apply an initialization voltage across a gate and a source of the drive transistor, the initialization voltage being higher than a threshold voltage of the drive transistor and according to a state of deterioration of the drive transistor.

With this configuration, an excessive voltage is not applied to the drive transistor in an initial stage of driving. Therefore, deterioration of the drive transistor can be reduced.

Also, the initialization voltage adjustment unit may adjust the length of the initialization period during which the initialization voltage is applied to the drive transistor, according to a state of deterioration of the drive transistor.

With this configuration, a stable initialization voltage can be applied to the drive transistor. Thus, it is possible to further reduce deterioration of the drive transistor.

### Other Embodiments

The embodiment has been described so far as exemplification of the technique disclosed in this application. However, the technique in the present disclosure is not limited to this, and is applicable to an embodiment in which modifications, replacements, additions, omissions are made as needed. Also, a new embodiment may be devised by combining components described in the aforementioned embodiment.

Thus, other embodiments are collectively described below.

For instance, the pixel circuits 20 in the display device 10 according to the present disclosure are not limited to the above-described pixel circuits 20, and may be pixel circuits 20 having another configuration. Alternatively, the operation of the pixel circuits 20 is not limited to the operation illustrated in the above-described timing chart, and may be another operation. Alternatively, the transistors in the pixel circuits 20 may be P-channel type transistors or may be N-channel type transistors.

As described above, the embodiment has been described as exemplification of the technique in the present disclosure. For this purpose, the accompanying drawings and detailed description have been provided.

Therefore, the components illustrated in the accompanying drawings and detailed description include not only required components for solving the problem, but also not required components for solving the problem for the purpose of exemplifying the aforementioned technique. Therefore, it should be understood that those not required components are never determined to be required simply because those not required components are described in the accompanying drawings and detailed description.

Also, since the above-described embodiments are provided for the purpose of exemplifying the technique in the present disclosure, various modifications, replacements, additions, omissions may be made in the claims and its equivalent range.

### INDUSTRIAL APPLICABILITY

The present disclosure can be utilized for an EL display (EL display panel) and a drive method for the display. Specifically, the present disclosure can be utilized for a video camera, a digital camera, a goggle type display, a navigation system, a sound reproduction system (such as a car audio, an audio component), a computer, a game machine, a mobile information terminal (such as a mobile computer, a mobile phone, a mobile game console, or a digital book), an image reproduction device (specifically, a device that reproduces data in a recording medium such as a Digital Versatile Disc (DVD) and includes a display that can display an image) including a recording medium.

### REFERENCE SIGNS LIST

2, 20 pixel circuit (pixel)

10 display device

30 initialization voltage adjustment unit

Cs pixel capacitor

EL light emitter

SL signal line

Tr1 sampling transistor

Tr2 first switching transistor

Tr3 second switching transistor

Tr4 third switching transistor

Trd drive transistor

1. A drive method for a display device in which a plurality of pixels are disposed in rows and columns,
each of the plurality of pixels including a light emitter that emits light in an amount according to a magnitude of a current supplied, and a drive transistor that supplies a current according to a magnitude of a video signal to the light emitter,
the drive method for the display device, comprising
applying an initialization voltage across a gate and a source of the drive transistor by an initialization voltage adjustment unit in an initialization period for initializing the drive transistor, the initialization voltage being higher than a threshold voltage of the drive transistor and according to a state of deterioration of the drive transistor.

2. The drive method for a display device according to claim 1,
wherein the initialization voltage has a voltage value obtained by adding a predetermined voltage to the threshold voltage of the drive transistor, the predetermined voltage varying by an amount equal to an amount of variation in the threshold voltage.

3. The drive method for a display device according to claim 1,
wherein the initialization voltage is increased as time elapses.

4. The drive method for a display device according to claim 1,
wherein the initialization voltage adjustment unit adjusts a length of the initialization period according to the state of deterioration of the drive transistor.

5. The drive method for a display device according to claim 1,
wherein before the initialization voltage is applied across the gate and the source of the drive transistor, the initialization voltage adjustment unit estimates the state of deterioration of the drive transistor from video data obtained by light-emission of the light emitter, and sets the initialization voltage.

6. The drive method for a display device according to claim 1,
wherein before the initialization voltage is applied across the gate and the source of the drive transistor, the initialization voltage adjustment unit estimates the state of deterioration of the drive transistor from the threshold voltage of the drive transistor or measurement data of a current which flows through the drive transistor, and sets the initialization voltage.

7. A display device comprising:
a plurality of pixels which are disposed in rows and columns, and each of which includes a light emitter that emits light in an amount according to a magnitude of a current supplied, and a drive transistor that supplies a current according to a magnitude of a video signal to the light emitter; and
an initialization voltage adjustment unit configured to apply an initialization voltage for initializing the drive transistor to the drive transistor,
wherein the initialization voltage adjustment unit is configured to apply an initialization voltage across a gate and a source of the drive transistor, the initialization voltage being higher than a threshold voltage of the drive transistor and according to a state of deterioration of the drive transistor.

8. The display device according to claim 7,
wherein the initialization voltage adjustment unit is configured to adjust a length of an initialization period during which the initialization voltage is applied to the drive transistor, according to the state of deterioration of the drive transistor.
